(19) United States
(12) Patent Application Publication
(10) Pub. No.: US 2017/0314132 A1
(43) Pub. Date: Nov. 2, 2017

(54) PLASMA REACTOR HAVING DIVIDED ELECTRODES

(71) Applicant: RETRO-SEMI TECHNOLOGIES, LLC., Beverly, MA (US)

(72) Inventors: Dong-Soo KIM, Kyeounggi-do (KR); Min-Su JOO, Kyeounggi-do (KR)

(21) Appl. No.: 15/484,706

(22) Filed: Apr. 11, 2017

Related U.S. Application Data
(60) Provisional application No. 62/329,492, filed on Apr. 29, 2016.

(51) Int. Cl. C23C 16/505; H01J 37/32; C23C 16/458; C23C 16/455; C23C 16/52

(52) U.S. Cl. CPC C23C 16/505; H01J 37/32082; H01J 37/32532; H01J 37/3244; C23C 16/455; C23C 16/52; C23C 16/458; H01J 2237/3321

(57) ABSTRACT

A plasma reactor for generating a plasma for use in depositing a thin film on a large area wafer, such as in the manufacturing of solar cells. A plasma electrode unit in the plasma reactor is divided into a plurality of discrete electrodes, and RF electric power is sequentially applied to the divided plasma electrodes in accordance with a predefined sequence of temporal intervals as controlled by a sequence control unit. The sequential application of RF power across the divided plasma electrode unit resolves a standing wave problem in the plasma applied over a large area corresponding to a large area wafer.

### STATEMENT REGARDING FEDERALLY SPONSORED RESEARCH OR DEVELOPMENT

n/a

### BACKGROUND OF THE INVENTION

Chemical vapor deposition (CVD) technology, used in a process for manufacturing an integrated circuit (IC) such as a semiconductor, is a technique which applies energy such as heat or electric power to a gaseous raw material including chemicals to increase a reactivity of the raw material gas and induce a chemical reaction, so that a raw material gas is adsorbed on a semiconductor wafer to form a thin film or an epitaxial layer, and is mainly utilized to produce a semiconductor, a silicon oxide film, a silicon nitrogen film, an amorphous silicon thin film.

In general, the yield rate of a semiconductor is improved if production occurs at a relatively lower temperature during a manufacturing process because the number of product defects are reduced. However, chemical vapor deposition technology causes a chemical reaction by applying energy with heat or light, so that temperature inevitably increases, making it difficult to improve the yield rate of the semiconductor.

As an approach to solving the temperature-induced problem, a plasma enhanced chemical vapor deposition (PECVD) method enables chemical vapor deposition even at a low temperature. In the PECVD method, a chemical reaction is induced to deposit a thin film by chemically activating a reactant using plasma instead of heat, electricity, or light to increase the reactivity of the raw material gas. To achieve this in PECVD, chemical activity is improved to generate a chemical reaction at a low temperature by supplying RF power from an RF oscillator to the raw material gas existing in a gaseous state, thereby converting the reactant into plasma.

Generally, a higher deposition speed can be obtained using the PECVD method as frequency of the RF power becomes higher. At a very high frequency (VHF) condition, the high deposition speed increases, resulting in an improvement in productivity, efficiently reducing manufacturing costs in semiconductor manufacturing processes. Accordingly, it is common to perform the PECVD processing under a VHF conditions to improve manufacturing efficiency. For example, RF frequency is typically provided by the RF oscillator at a high frequency of 10 MHz or higher, and preferably, 13.56 MHz, 27.12 MHz, or 40.68 MHz.

The PECVD process performed in the typical semiconductor manufacturing may be performed under high frequency conditions because semiconductor wafers are relatively small. However, when a semiconductor wafer is large, for example, when the wafer is larger than the semiconductor wafer used in a typical processes, such as for solar cell manufacturing, there occurs a problem in which it is difficult to constantly maintain a wide plasma corresponding to the large area wafer. In other words, a plasma non-uniformity problem exists with larger wafers.

The non-uniform plasma is caused by a standing wave due to a large-area wafer used in a solar cell manufacturing process. The standing wave refers to a wave combination of waves occurring when waves having the same amplitude and frequency are moved in opposite directions, and refers to a wave that only vibrates in the stopped state but does not proceed. Accordingly, since the magnitude of RF power on the surface of the electrode varies due to standing waves formed along a surface of the plasma electrode, the plasma lacks uniformity.

Due to the non-uniformity of plasma occurring due to a standing wave in a plasma reactor under a high frequency condition, characteristics and the deposition rate or etching rate of a thin film, formed at a site where the density of plasma is relatively low, differs as compared with a site where the density of plasma is high, so that productivity of such larger wafers is compromised.

### BRIEF SUMMARY OF THE INVENTION

The present invention relates to a plasma reactor and, more particularly, to a plasma reactor used for generating a plasma for use in manufacturing products having a large wafer surface area, such as a thin film solar cell. A plasma electrode unit in a plasma reactor is divided into a plurality of parts and RF electric power is sequentially applied to the divided plasma electrode parts to solve a standing wave problem on the plasma electrode. Absent the divided plasma electrode, high frequency RF electric power applied to form the plasma over a large area corresponding to the large wafer surface area can result in plasma imbalance due to a standing wave phenomenon.

According to an aspect of the present invention, there is provided a plasma reactor for processing plasma, the plasma reactor comprising a plasma electrode unit divided into a plurality of parts or electrodes, a process gas inlet or injection port for injecting a process gas to a lower portion of the divided plasma electrode unit, a wafer disposable at a lower end of the plasma electrode unit and on which the process gas converted into plasma is deposited, an RF electric power unit for supplying RF electric power, and a sequence control unit, including a sequence control circuit, for matching the divided plasma electrodes to a predefined sequence, whereby RF power is sequentially applied to only one plasma electrode at a time.

The sequence control unit further comprises a voltage drop unit for selectively lowering the voltage of the applied RF electric power from the RF electric power unit and controls the application of the RF power to the divided plasma electrodes.

The divided plasma electrode unit includes at least a first plasma electrode, a second plasma electrode, a third plasma electrode, and a fourth plasma electrode that are spaced apart from each other. The sequence control unit matches each plasma electrode with a temporal instance in an activation sequence.

Further, the sequence control unit further comprises a phase modulation unit for converting the frequency of the RF power through phase modulation.

The divided plasma electrode units or electrodes are spaced apart at the same distance from each other in correspondence to the shape of the wafer, are horizontally disposed in the same plane, and are insulated from each other through an insulator.

The plasma reactor may further comprise a plurality of process gas injection ports for injecting a process gas into the divided plasma electrode units or electrodes.

The plasma reactor may further comprise a chamber including a partition wall extending downward so that the process gas injected into lower portions of the divided plasma electrode units or electrodes is shielded, and the chamber is open downward for depositing the formed plasma on the wafer below, whereby each electrode generates plasma from the respective process gas.

It should be understood that different embodiments of the invention, including those described under different aspects of the invention, are meant to be generally applicable to all aspects of the invention. Any embodiment may be combined with any other embodiment unless inappropriate. All examples are illustrative and non-limiting.

The plasma reactor having the divided electrodes according to the present invention solves a standing wave problem and a plasma imbalance problem in the plasma reactor that would otherwise occur due to use of high frequency RF power applied over a large area wafer such as in the manufacturing of a solar cell. Manufacturing efficiency and productivity of a such a product are improved even in a plasma reactor using a large area wafer.

### BRIEF DESCRIPTION OF THE SEVERAL VIEWS OF THE DRAWINGS

Other features and advantages of the present invention will be apparent from the following detailed description of the invention, taken in conjunction with the accompanying drawings of which:

FIG. 1 illustrates a section of a plasma reactor having divided plasma electrodes according to an exemplary embodiment of the present invention;

FIG. 2 schematically illustrates the application of RF power according to a predefined sequence executed by a sequence control unit of the plasma reactor of FIG. 1; and

FIG. 3 schematically illustrates the divided plasma electrodes of FIG. 1 connected to a plurality of output terminals of the sequence control unit, respectively.

### DETAILED DESCRIPTION OF THE INVENTION

This application claims priority of U.S. Prov. Pat. Appl. No. 62/329,492, filed Apr. 29, 2016, the entirety of which is hereby incorporated by reference.

The embodiments described in the specification and the configuration illustrated in the drawings merely correspond to an exemplary embodiment of the present invention, and do not express all the technical spirit of the present invention.

The present invention relates to a plasma reactor, more particularly to a plasma reactor used for generating a plasma for use in manufacturing products having a large wafer area, such as a thin film solar cell. A plasma electrode in the plasma reactor is divided into a plurality of electrodes, and RF electric power is sequentially applied to the plurality of divided plasma electrodes in accordance with a predefined sequence to solve a standing wave problem associated with the plasma electrode of prior art plasma reactors. Absent the divided plasma electrode unit, high frequency RF electric power applied to form the plasma over a large area corresponding to the large wafer surface area can result in plasma imbalance or non-uniformity due to a standing wave phenomenon.

Hereinafter, exemplary embodiments of the present invention will be described in detail with reference to the accompanying drawings.

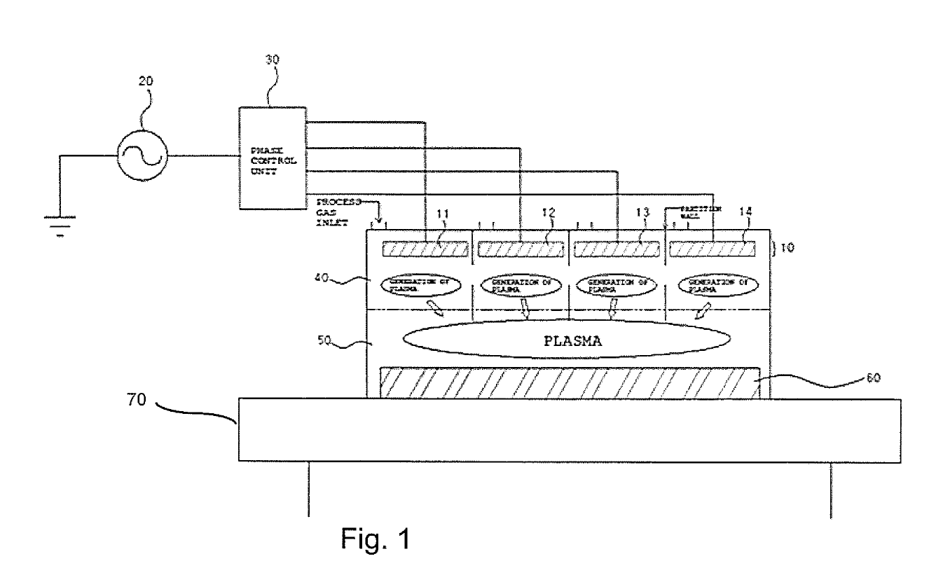

FIG. 1 illustrates a section of a plasma reactor having divided electrodes according to an embodiment of the present invention.

As illustrated in the drawings, the plasma reactor having divided electrodes according to the present invention includes: a buffer chamber 40 into which a process gas is introduced to generate plasma; a process chamber 50 in which the generated plasma is activated; a plasma electrode unit 10 divided into a plurality of parts or electrodes 11, 12, 13, 14 and formed above the buffer chamber 40 for converting the process gas into plasma when RF electric power is applied thereto; a gas supply unit (not illustrated) for supplying the process gas into the buffer chamber 40; an RF electric power supply unit 20 for supplying the RF electric power applied to the plasma electrode unit 10; and a sequence control unit 30 for controlling the RF electric power applied to each of the plasma electrodes of the divided plasma electrode unit 10.

The plasma reactor having divided electrodes according to the present invention is configured for operation with a wafer substrate 60 on which is deposited the plasma generated from process gas in the buffer chamber 40 by the divided plasma electrodes 11, 12, 13, 14 and activated within the process chamber 50. The substrate is disposed on a substrate support 70 for supporting the substrate.

In the plasma reactor having divided electrodes according to the present invention, the RF electric power supplied by the RF power supply unit 20 is supplied to each electrode of the divided plasma electrode unit 10 through the sequence control unit 30, and the RF power is sequentially supplied to each of the divided plasma electrodes in correspondence to a sequence of RF power applications performed by the sequence control unit 30.

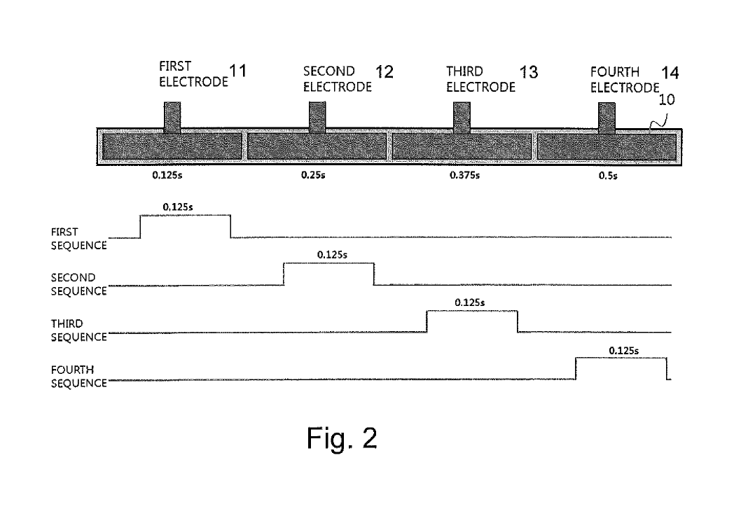

As illustrated in FIG. 1, the plasma electrode unit 10 according to an exemplary embodiment of the present invention is divided into four discrete electrodes 11, 12, 13, 14, but the present invention is not limited thereto, and the plasma electrode unit 10 may have a smaller or larger number of electrodes in other embodiments of the present invention. In the embodiment which will be described below, an embodiment including the plasma electrode unit 10 divided into four parts of FIG. 2, that is, the first electrode 11, the second electrode 12, the third electrode 13, and the fourth electrode 14 will be described.

The configuration of the divided plasma electrode unit 10 is provided to solve a standing wave problem caused by supplying VHF RF electric power to a large area electrode corresponding to the large area wafer 60, and is mutually divided to receive electric power, respectively, and does not cause a standing wave problem as compared with an integral electrode unit according to the related art. In the exemplary embodiment of the present invention, the divided plasma electrode unit 10 may be insulated through a known insulator for mutual insulation between individual electrodes 11, 12, 13, 14.

Furthermore, in a further embodiment of the present invention, the process chamber 50 as well as the buffer chamber 40 may have a plurality of process gas inlets or injection ports in correspondence to the number of electrodes of the divided plasma electrode unit 10, rather than a single injection port as illustrated in FIG. 1. The plurality of process gas inlets in this embodiment are allocated to each electrode of the plasma electrode unit 10 to inject a respective process gas with respect to each discrete electrode. To this end, the process chamber 50 as well as the buffer chamber 40 may include one or more partition walls extending downwards between the electrodes such that the process chamber 50 is partially divided into regions of separate gases. A lower side of the buffer chamber 40 is open for deposition of plasma on the substrate within the process chamber 50.

The divided plasma electrode unit 10 is configured to receive high frequency power at the plural electrodes 11, 12, 13, 14 from the source 20 through the sequence control unit 30.

The sequence control unit 30 is a constituent element for controlling RF electric power applied to each of the four divided plasma electrodes 11, 12, 13, 14 in sequence. A pre-defined sequence is stored in conjunction with the sequence control unit by which each of the divided plasma electrode units is matched to a temporal instance within the sequence. Accordingly, RF power is sequentially applied to the one plasma electrode associated with the respective temporal instance within the predefined sequence. Over the course of the sequence, RF power is applied to each plasma electrode sequentially. Once the sequence control unit has sequentially energized the divided plasma electrodes according to the sequence, the sequence is repeated.

In the illustrated embodiment, there are four plasma electrodes 11, 12, 13, 14 and RF power is sequentially applied to the four electrodes of the divided plasma electrode units 10 by the sequence control unit 30 according to the predefined sequence. As a result, the process gas reacts with each of the four electrodes of the divided plasma electrode unit 10 to generate plasma corresponding to the entire large area wafer 60. In this case, because the plasma is separately generated by each of the four electrodes of the divided plasma electrode unit 10, each respective reaction area is relatively small. Thus, it is not necessary to apply high-frequency RF power, whereby the non-uniformity problem of plasma associated with the prior art is solved and uniform plasma corresponding to the large-area wafer 60 may be formed.

The sequence control unit 30 of the present invention further includes a voltage drop unit. As described above, since the plasma electrode unit 10 of the present invention is divided into plural plasma electrodes each for independently generating plasma, there is no need to apply RF electric power of a high voltage such as employed with a conventional large-area plasma electrode. By applying the RF electric power to each of the plural electrodes 11, 12, 13, 14 of the divided plasma electrode units 10 after lowering the voltage through the voltage drop unit, power efficiency is enhanced.

Further, since the sequence control unit 30 enables generation of plasma even at a relatively low frequency RF power via the discrete electrodes of the divided plasma electrode unit 10, it can further be provided with a phase modulator for down-converting the frequency of the received RF power.

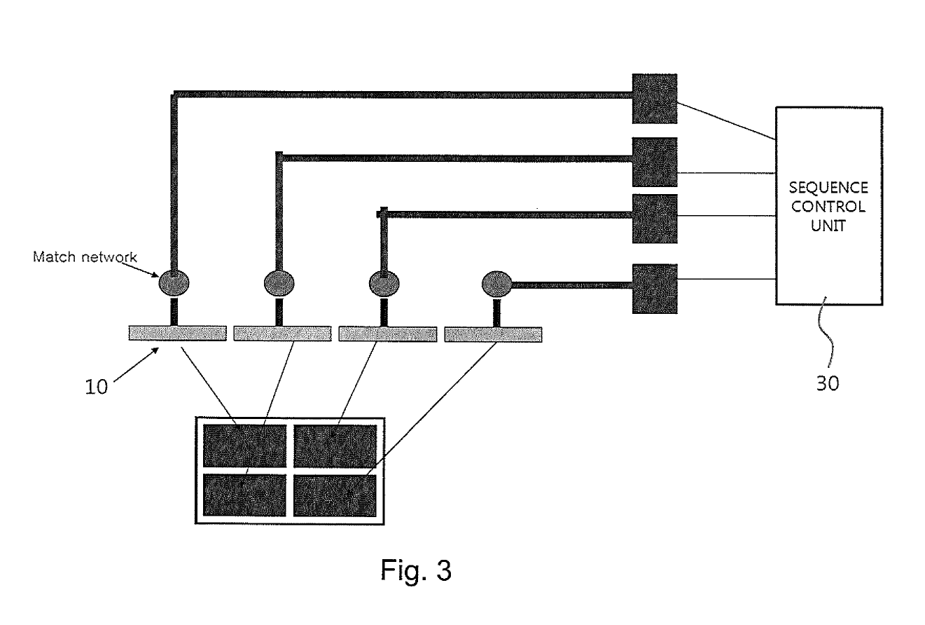

FIG. 2 illustrates the application of RF power according to a sequence executed by the sequence control unit 30. Further, FIG. 3 schematically illustrates the divided plasma electrode unit connected to each of a plurality of output terminals of the sequence control unit 30.

As shown, in the sequence control unit 30, the sequentially performed four temporal instances are continuously repeated at a preset time interval, with each temporal instance matched to a respective electrode of the divided plasma electrode unit 10.

In the illustrated embodiment of FIG. 2, the first temporal instance is assigned to the first electrode unit 11, the second instance is assigned to the second electrode unit 12, the third instance is assigned to the third electrode unit 13, and the fourth instance is assigned to the fourth electrode unit 14. As noted, the number of the temporal instances within a sequence corresponds to the number of electrodes. Thus, there may be more or less than four temporal instances per sequence depending upon the embodiment.

The sequence control unit 30 applies voltage to the electrode of the divided plasma electrode unit 10 assigned to the temporal instance according to the defined sequence.

The sequence control unit 30 is made up of an integrated circuit that includes a rectifier circuit and a sequence control circuit for processing the applied electric power from the RF power supply and includes a plurality of output terminals, each of which outputs RF power in accordance with the plurality of temporal instances. Therefore, when the RF power is applied to the sequence control unit 30, the RF power is applied to one of the divided plasma electrodes corresponding to the temporal instance of the predefined sequence.

In one embodiment of the present invention, the sequence control unit 30 may further include a phase modulator for changing the frequency of the RF power. With such a phase modulator, prior to the application of the RF power from the sequence control unit 30, the RF power is frequency converted through phase modulation, and the RF power may be applied at a lower frequency. Since each electrode of the divided plasma electrode unit is smaller than the plasma electrode of the prior art, it is possible to activate the same resulting plasma through RF power having a lower frequency.

As illustrated in FIG. 3, in an exemplary embodiment of the present invention, 5 KW RF power having a frequency of 60 MHz, which is relatively low as compared with VHF, is applied to the divided plasma electrodes, respectively. The RF electric power can be provided through the voltage drop unit of the sequence control unit 30. Through an arbitrary sequence defined within the sequence control unit 30, the RF power is applied to only one plasma electrode of the divided plasma electrodes according to the present temporal instance within the sequence, while power is not applied to the remaining divided plasma electrodes. The RF power applied to the each divided, insulated plasma electrode produces plasma, but because the activity is sequentially and consistently performed, the same effect as obtained when electric power of a total of 20 KW is supplied to a conventional electrode can be obtained.

The plasma reactor having the divided electrodes according to the present invention solves the standing wave problem and the plasma non-uniformity problem that occurs due to use of a large-area wafer 60 such as in the manufacturing of a solar cell through the above configuration. Accordingly, the present invention solves all the disadvantages of the plasma reactors of the prior art, and enhances a manufacturing efficiency of a product even in a plasma reactor using a large-area wafer 60, thereby improving productivity.

Although an exemplary embodiment of the plasma reactor having divided electrodes according to the present invention has been described in detail, it is merely a specific example for illustrating the general concepts of the present invention, and is not intended to limit the scope of the present invention. It is clearly understood by those skilled in the art to which the present invention pertains that modifications based on the technical spirit of the present invention can be made in embodiments other than the disclosed embodiment.

What is claimed is:

1. A plasma reactor for plasma processing comprising:
a buffer chamber;
a divided plasma electrode unit comprising plural discrete electrodes and disposed within the buffer chamber;
at least one process gas injection port for receiving a respective process gas and for injecting the respective process gas into the buffer chamber proximate the discrete electrodes;
a process chamber in which a plasma can be formed by the discrete electrodes selectively energizing the process gas;
a substrate support disposed at a lower end of the process chamber for supporting a substrate onto which the plasma is deposited;
an RF electric power unit for supplying RF electric power; and
a sequence control unit for associating one discrete electrode with each of plural temporal intervals within a predefined sequence and for sequentially applying RF electric power, received from the RF electric power unit, to the plural discrete electrodes according to the plural temporal intervals of the predefined sequence

2. The plasma reactor of claim 1, wherein the sequence control unit further comprises a voltage drop unit for lowering the voltage of the RF electric power received from the RF electric power unit prior to being applied to the plural discrete electrodes by the sequence control unit.

3. The plasma reactor of claim 2, wherein
the divided plasma electrode units include a first plasma electrode unit, a second plasma electrode unit, a third plasma electrode unit, and a fourth plasma electrode unit that are spaced apart from each other in a substantially horizontal plane,
the predefined sequence comprises four temporal intervals, and
the sequence control unit associates one temporal interval within the predefined sequence with a respective one of the plural discrete electrodes.

4. The plasma reactor of claim 1, wherein the sequence control unit further comprises a phase modulation unit for converting the frequency of the RF electric power received from the RF electric power unit through phase modulation.

5. The plasma reactor of claim 1, wherein the discrete electrodes of the divided plasma electrode unit are:
spaced apart from each other in a substantially horizontal plane;
arrayed in correspondence with a shape of a wafer to be disposed on the substrate support; and
are insulated from each other through an insulator.

6. The plasma reactor of claim 1, wherein the at least one process gas injection port comprises plural process gas injection ports, each process gas injection port being associated with a respective one of the plural discrete electrodes.

7. The plasma reactor of claim 6, further comprising:
a partition wall extending downward from the top of the buffer chamber and between the plural discrete electrodes within the buffer chamber for isolating the process gases from each other, the buffer chamber being downwardly open to allow the process gases to be energized by the respective discrete electrodes and to form the plasma therefrom within the process chamber.
